(19) United States
(12) Patent Application Publication
(10) Pub. No.: US 2016/0141317 A1
(43) Pub. Date: May 19, 2016

(54) PIXEL ISOLATION REGIONS FORMED WITH DOPED EPITAXIAL LAYER

(71) Applicant: SEMICONDUCTOR COMPONENTS INDUSTRIES, LLC, Phoenix, AZ (US)

(72) Inventor: Daniel Tekleab, Hayward, CA (US)

(73) Assignee: SEMICONDUCTOR COMPONENTS INDUSTRIES, LLC, Phoenix, AZ (US)

(21) Appl. No.: 14/543,793

(22) Filed: Nov. 17, 2014

(51) Int. Cl. H01L 27/146

(52) U.S. Cl. CPC H01L 27/1463; H01L 27/14643; H01L 27/14634; H01L 27/14683

(57) ABSTRACT

An image sensor may include isolation regions that are formed in between photodiodes. These isolation regions may prevent cross-talk and improve the performance of the image sensor. The isolation regions may be made of epitaxial silicon. The epitaxial silicon may be grown in trenches formed in a substrate using an etching process. Portions of the substrate may be protected from the etching process with a hard mask layer. Photodiodes may later be implanted in these protected portions of the substrate after the isolation regions have been formed. The epitaxial silicon may be boron-doped or antimony-doped epitaxial silicon with a concentration of boron or antimony between 10¹⁶ cm³ and 10¹⁸ cm³.

### BACKGROUND

The present invention relates to integrated circuits and, more particularly, to forming isolation regions in CMOS (complementary metal oxide semiconductor) image sensors.

Digital cameras are often provided with digital image sensors such as CMOS image sensors. Digital cameras may be stand-alone devices or may be included in electronic devices such as cellular telephones or computers. A typical CMOS image sensor has an image sensor pixel array containing thousands or millions of pixels. Each pixel includes a photosensitive element such as a photodiode formed in a substrate. Isolation regions may be formed in the substrate between photodiodes to reduce crosstalk between photodiodes.

To improve image quality, it is often desirable to increase the number and density of pixels on an image sensor. As pixel density increases, pixels necessarily are pushed closer and closer together, increasing the likelihood of cross-talk. Isolation regions help alleviate cross-talk and allow the photodiodes to have a greater full well capacity and therefore an improved image quality.

Some methods for forming isolation regions include ion implantation. However, implanted ions are difficult to precisely control and often diffuse laterally, making it impossible to produce an abrupt junction. Consequently, full well capacity must be sacrificed in order to provide sufficient isolation between photodiodes. Alternatively, deep trench isolation methods may be used in which a liner oxide is grown in a isolation trench. However, this method introduces defects due to lattice mismatch, thus resulting in higher dark current and hot pixels.

It would therefore be desirable to be able to provide improved methods for forming isolation regions in image sensors.

### BRIEF DESCRIPTION OF THE DRAWINGS

FIG. 1 is a diagram of an illustrative electronic device having an image sensor in accordance with an embodiment of the present invention.

FIG. 2 is a top view of an illustrative image sensor pixel array in accordance with an embodiment of the present invention.

FIG. 3 is a top view of a portion of an illustrative image sensor pixel array having isolation structures in accordance with an embodiment of the present invention.

FIG. 4 is a top view of illustrative color filter elements that may be used in an image sensor pixel array in accordance with an embodiment of the present invention.

FIG. 5 is a cross-sectional side view of a portion of an image sensor with a hard mask layer in accordance with an embodiment of the present invention.

FIG. 6 is a cross-sectional side view of the image sensor of FIG. 5 after silicon etching in the P-well isolation region has formed a trench in accordance with an embodiment of the present invention.

FIG. 7 is a cross-sectional side view of the image sensor of FIG. 6 after a p-doped silicon epitaxial growth layer has been formed in the trench in accordance with an embodiment of the present invention.

FIG. 8 is a cross-sectional side view of the image sensor of FIG. 7 after the hard mask layer has been etched in accordance with an embodiment of the present invention.

FIG. 9 is a block diagram of a processor system employing the embodiments of FIGS. 1-8 in accordance with an embodiment of the present invention.

### DETAILED DESCRIPTION

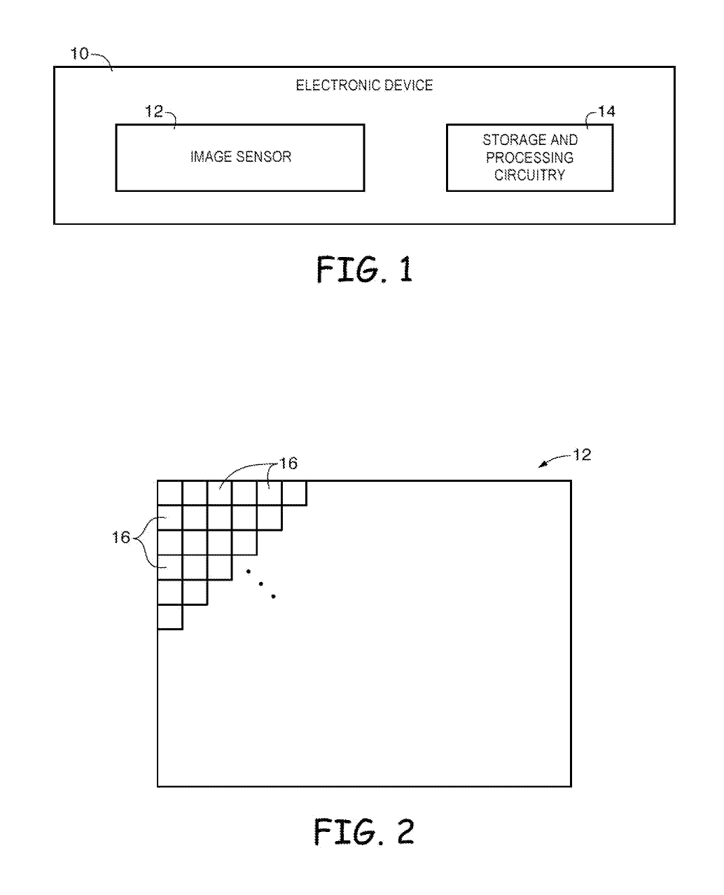

Digital image sensors are widely used in digital cameras and in electronic devices such as cellular telephones, computers, and computer accessories. An illustrative electronic device 10 with an image sensor 12 and storage and processing circuitry 14 is shown in FIG. 1. Electronic device 10 may be a digital camera, a computer, a computer accessory, a cellular telephone, or other electronic device. Image sensor 12 may be part of a camera module that includes a lens or may be provided in an electronic device that has a separate lens. During operation, the lens focuses light onto image sensor 12. Image sensor 12 may have an array of image sensor pixels containing photosensitive elements such as photodiodes that convert light into digital data. Image sensors may have any number of pixels (e.g., hundreds, thousands, millions, or more). A typical image sensor may, for example, have millions of pixels (e.g., megapixels).

Image data from image sensor 12 may be provided to storage and processing circuitry 14. Storage and processing circuitry 14 may process the digital image data that has been captured with sensor 12. The processed image data may be maintained in storage in circuitry 14. The processed image data may also be provided to external equipment. Storage and processing circuitry 14 may include storage components such as memory integrated circuits, memory that is part of other integrated circuits such as microprocessors, digital signal processors, or application specific integrated circuits, hard disk storage, solid state disk drive storage, removable media, or other storage circuitry. Processing circuitry in storage and processing circuitry 14 may be based on one or more integrated circuits such as microprocessors, microcontrollers, digital signal processors, application-specific integrated circuits, image processors that are incorporated into camera modules, other hardware-based image processing circuits, combinations of these circuits, etc. If desired, image sensor 12 and processing circuitry 14 may be implemented using a single integrated circuit or may be implemented using separate integrated circuits.

An illustrative image sensor pixel array 12 is shown in FIG. 2. Image sensor 12 of FIG. 2 has an array of image pixels 16. Pixels 16 are typically organized in rows and columns. Each pixel contains a photosensitive element such as a photodiode and corresponding electrical components (e.g., transistors, charge storage elements, and interconnect lines for routing electrical signals).

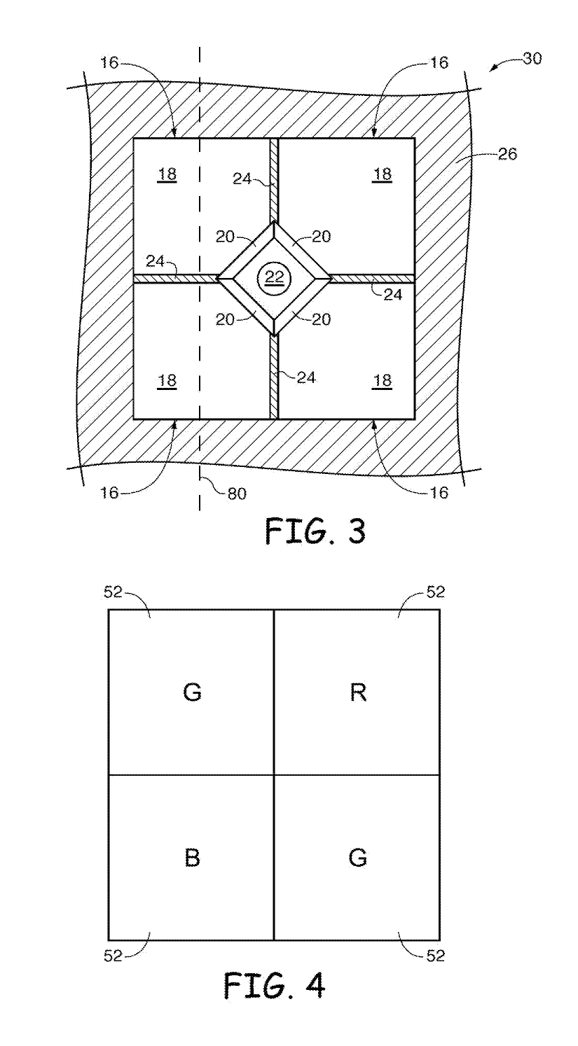

FIG. 3 is a diagram showing a portion of an array of image sensor pixels 16. In the example of FIG. 3, each pixel 16 has a photodiode 18. Photodiodes 18 may be formed in substrate 30. Photons may strike photodiodes 18 and generate charge. Charge can be transferred to floating diffusion region 22 by turning transfer gates 20 momentarily on. Photodiodes 18 within pixel 16 may be separated by isolation regions 24. Isolation region 26 may separate photodiodes 18 from array transistors and from adjacent pixels.

If desired, each pixel 16 may include a separate floating diffusion node. The example of FIG. 3 in which four pixels 16 share floating diffusion node 22 is merely illustrative.

Substrate 30 may be a silicon substrate. Substrate 30 may, for example, be a doped substrate such as a p-type substrate or a p+ substrate. Substrate 30 may have an epitaxial layer such as a p-type or n-type epitaxial layer. If desired, substrate 30 may be a silicon-on-insulator (SOI) substrate and may have a buried oxide layer (BOX). Isolation regions 24 and 26 may be p-well regions or n-well regions. Isolation regions 24 and 26 may be formed by silicon etching trenches into substrate 30 and forming a high concentration p-type or n-type doped epitaxial layer in the trenches.

Incoming light may pass through a color filter before striking one of photodiodes 18 of FIG. 3. FIG. 4 is a top view of illustrative color filter elements that may filter light for pixels 16 of FIG. 3. The color filter pattern of FIG. 4 has red (R), green (G), and blue (B) color filter elements 52 and is sometimes referred to as a Bayer pattern. The pattern of FIG. 4 is merely illustrative, however. If desired, other patterns and/or other filter elements (e.g., filter elements having different spectral responses) may be used.

The quality of the images captured using image sensor 12 may be influenced by a variety of factors. For example, the size of the pixel array in image sensor 12 may have an impact on image quality. Large image sensors with large numbers of image pixels will generally be able to produce images with higher quality or resolution than smaller image sensors having fewer image pixels. Additionally, the full well capacity of photodiodes 18 in image sensor 12 may have an impact on image quality. Full well capacity is a measure of the amount of charge an individual pixel can hold before becoming saturated. Pixels becoming saturated may decrease the quality of an image. Therefore, it is desirable for a pixel to be able to hold as much charge as possible so that the pixel becomes saturated less often.

In order to increase the number of pixels and improve image quality, it may be desirable to decrease the size of the pixels. It also may be desirable to decrease the pixel pitch of an image sensor, which is a measure of the distance between equivalent pixels. For example, pixel pitches for image sensors may be 10 microns or less, 5 microns or less, one micron or less, etc.

As pixel pitch is reduced, cross-talk between pixels is more likely as neighboring photodiodes become closer together. In order to increase the number of pixels while still preventing cross-talk, full well capacity has to be sacrificed, as neighboring photodiodes with greater full well capacity will be more susceptible to cross-talk. Consequently, full well capacity is reduced to achieve maximum pixel density.

It may be desirable to increase the number of pixels while preventing cross-talk without sacrificing full well capacity. Formation of improved isolation regions such as isolation regions 24 of FIG. 3 may enable an improved pixel array with minimal cross-talk and maximum full-well capacity.

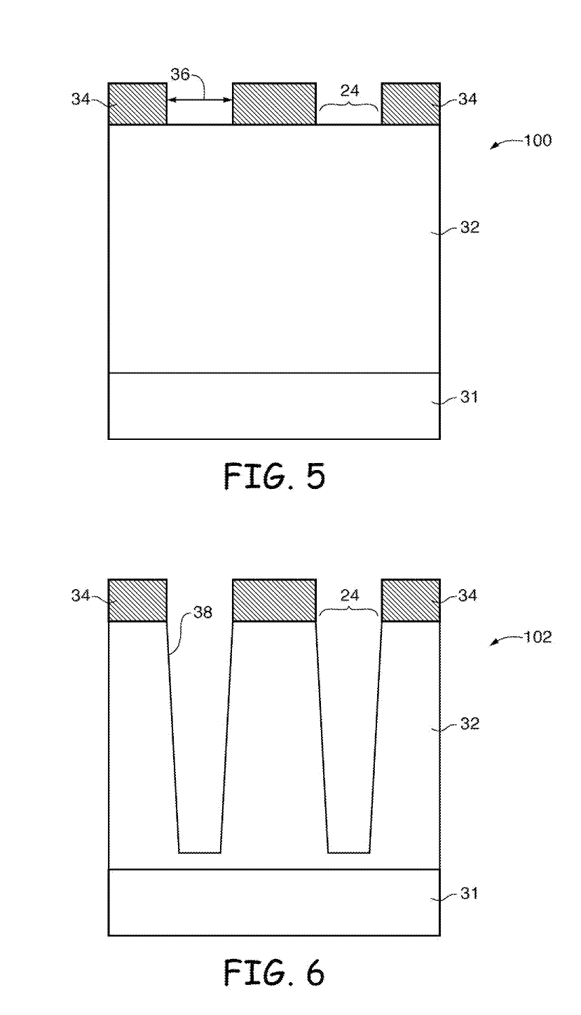

Isolation regions such as isolation regions 24 of FIG. 3 may be formed using a multi-step approach in which epitaxial silicon is grown in trenches formed in regions 24. Such growth regions may be doped with high concentrations of dopants such as boron or other suitable dopants. These growth regions may form isolation regions having a high concentration of dopants to thereby form an abrupt junction. The junction is the region where one type concentration of dopants (eg. P-type) ends and the opposite type concentration of dopants begins (eg, N-Type). An abrupt junction may be more effective than a non-abrupt junction at isolating photodiodes and reducing cross-talk by preventing charge carriers from wandering from one photodiode to the next. FIGS. 5-8 show cross-sectional side views of an illustrative image sensor at sequential stages of the isolation region forming process. FIG. 8 may, for example, correspond to a cross-section taken along line 80 of FIG. 3. The isolation regions formed may correspond to, for example, isolation region 24 or 26 of FIG. 3.

At step 100 of FIG. 5, hard mask 34 is formed over portions of epitaxial layer 32 where photodiodes will later be implanted. Epitaxial layer 32 may be a p-type layer or n-type layer deposited on an upper surface of substrate layer 31. Substrate 31 may be a p+ or p-type silicon substrate or a buried oxide (BOX) layer. If desired, layer 31 may be an n-type substrate. Epitaxial layer 32 may, for example, be a p-type epitaxial layer that is doped with boron or other suitable dopants. Epitaxial layer 32 may be doped with boron or other suitable dopants at densities of 10¹⁴-10¹⁵ cm⁻³ or other suitable densities. Photodiodes may be formed in epitaxial layer 32. In the illustrated embodiment, the photodiodes are not formed in the epitaxial layer until after the isolation regions are formed. In alternate embodiments, the photodiodes may be formed in the epitaxial layer before the isolation regions are formed (e.g., before step 100). Photodiodes may be located in n-wells underneath hard mask 34. Hard mask 34 may be separately formed over each photodiode region. The segments of hard mask 34 may be separated by a distance 36. Distance 36 may, for example, be 3 micrometers, less than 3 micrometers, less than 1 micrometer, more than 3 micrometers, more than 10 micrometers, or any other suitable distance. Hard mask 34 may be formed from silicon nitride, a photoresist, or other suitable mask material.

At step 102 of FIG. 6, etching may occur at each p-well isolation region. This etching may be dry etching or wet etching. In wet etching, epitaxial layer 32 may be immersed in a bath of etchant. The etchant may be buffered hydrofluoric acid, potassium hydroxide, a solution of ethylene diamine and pyrocatechol, or any other suitable etchant. Hard mask 34 may be resistant to the etchant. Accordingly, hard mask 34 may prevent epitaxial layer 32 from being etched in the areas directly beneath hard mask 34. In the areas not covered by hard mask 34, the silicon etching may form trenches such as trench 38. The dimensions of trench 38 can be controlled during the etching process. For example, immersing epitaxial layer 32 in a bath of etchant for a longer period of time may result in a deeper trench. Trench 38 may be formed with widths of 10 microns or less, 3 microns or less, 1 micron or less, 0.5 microns or less, 0.3 microns or less, etc. It may be desirable to have isolation regions that extend from the surface of a substrate to a depth of, e.g. 3-5 microns, 3 microns or more, 4 microns or more, etc. Desired width vs. height aspect ratios for trench 38 may be, for example, approximately 1:8, 1:7 or greater, 1:8 or greater, 1:9 or greater, etc.

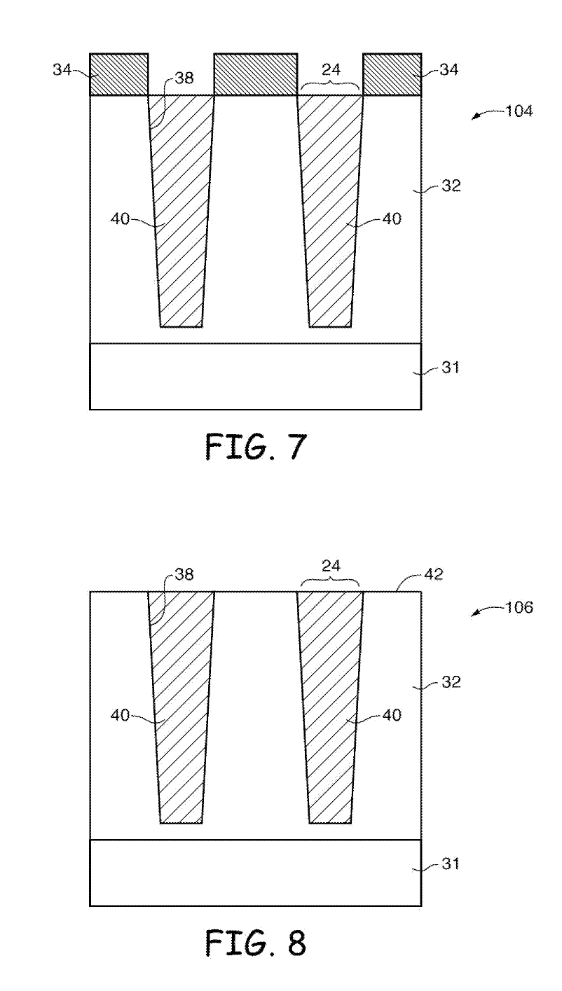

At step 104 of FIG. 7, doped p-type epitaxial layer 40 with a high concentration of dopants may be grown in trench 38. P-type epitaxial layer 40 may be a p-type epitaxial layer that is doped with boron or other suitable dopants. P-type epitaxial layer 40 may be doped at densities of 10¹⁴-10¹⁸ cm⁻³, densities of 10¹⁶-10¹⁸ cm⁻³, or a density of 10¹⁷ cm⁻³. If desired, doping may be done in situ such that the doping occurs while the epitaxial layer is being grown. The high doping concentration of p-type epitaxial layer 40 results in isolation regions being formed in each trench 38. Because the isolation region is formed using an epitaxially grown p-well, the isolation region has an abrupt junction between its high concentration dopant region and the surrounding N-type concentration dopant region. The epitaxially grown p-well has an abrupt junction compared to isolation regions formed with ion implantation, which have less abrupt junctions due to lateral diffusion of the implanted ions. The lateral diffusion of the implanted ions causes some of the ions in the high concentration dopant area to stray into the N-type concentration dopant area. The doped p-type epitaxial layer 40 formed at step 104 results in an isolation region that may reduce electrical cross-talk.

Epitaxial layer 40 may be formed using a variety of growth methods. For example, epitaxial layer 40 may be formed using vapor-phase epitaxy, liquid-phase epitaxy, or solid-phase epitaxy. Epitaxial layer may be formed via growth at any suitable temperature. Epitaxial layer may be formed via growth at temperatures of 650° C., less than 650° C., more than 650° C., 1200° C., more than 1200° C., or any other suitable temperature.

At step 106 of FIG. 8, hard mask 34 may be removed in an etching process. This etching may be dry etching or wet etching. After hard mask 34 has been removed in an etching process, chemical-mechanical planarization (CMP) may be performed to smooth surface 42.

After completing step 106, photodiodes may be implanted in the n-wells of epitaxial layer 32 between trenches 38. Alternatively, photodiodes may have been implanted in epitaxial layer before step 100, before step 102, before step 104, before step 106, or at another suitable time in the manufacturing process.

The aforementioned method of forming isolation regions with high concentration p-type epitaxial layers may be used in backside illumination sensors or front side illumination sensors. In backside illumination sensors, photodiodes are located in an epitaxial layer above an interlayer dielectric (ILD) containing metal interconnects. With this configuration, light reaches the photodiodes without having to pass through the ILD layer. In front side illumination sensors, photodiodes are located in an epitaxial layer below an ILD layer. With this configuration, light will travel through the ILD layer before reaching the photodiodes.

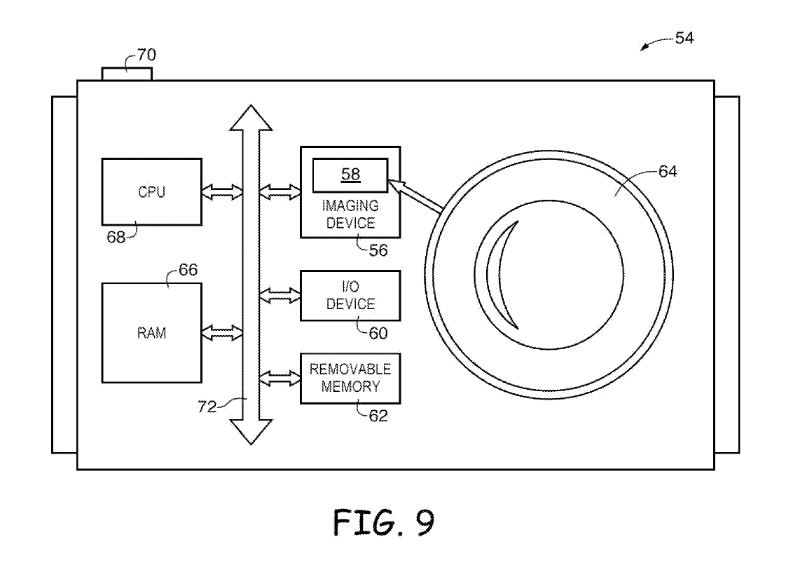

FIG. 9 shows in simplified form a typical processor system 54, such as a digital camera, which includes an imaging device 56. Imaging device 56 may include a pixel array 58 of the type shown in FIG. 2. Pixel array 58 may include isolation regions formed from an epitaxial layer such as those shown in FIG. 8. Processor system 54 is exemplary of a system having digital circuits that may include imaging device 56. Without being limiting, such a system may include a computer system, still or video camera system, scanner, machine vision, vehicle navigation, video phone, surveillance system, auto focus system, star tracker system, motion detection system, image stabilization system, and other systems employing an imaging device.

Processor system 54, which may be a digital still or video camera system, may include a lens such as lens 64 for focusing an image onto a pixel array such as pixel array 58 when shutter release button 70 is pressed. Processor system 54 may include a central processing unit such as central processing unit (CPU) 68. CPU 68 may be a microprocessor that controls camera functions and one or more image flow functions and communicates with one or more input/output (I/O) devices 60 over a bus such as bus 72. Imaging device 56 may also communicate with CPU 68 over bus 72. System 54 may include random access memory (RAM) 66 and removable memory 62. Removable memory 62 may include flash memory that communicates with CPU 68 over bus 72. Imaging device 56 may be combined with CPU 68, with or without memory storage, on a single integrated circuit or on a different chip. Although bus 72 is illustrated as a single bus, it may be one or more buses or bridges or other communication paths used to interconnect the system components.

Various embodiments have been described illustrating a method of forming an image sensor with an array of photodiodes in a substrate and a plurality of isolation regions that isolate each photodiode in the array. The isolation regions may be formed by performing an etching process that forms trenches in a substrate. In various embodiments, the substrate may be made of silicon, and the etching process may be a silicon etching process.

Before performing the etching process, a hard mask layer may be formed over a portion of the substrate. The hard mask layer may cover a portion of the substrate and prevent the covered portion from being affected by the etching process. After the etching process has occurred and the trenches have been formed, epitaxial silicon may be formed in the trenches. The epitaxial silicon may be a boron-doped or antimony-doped epitaxial silicon with a concentration between 10¹⁶ cm⁻³ and 10¹⁸ cm⁻³. The epitaxial silicon may be formed via epitaxial growth that occurs at temperatures between 600° C. and 700° C. The boron-doped epitaxial silicon may provide an abrupt junction between photodiodes that prevents cross-talk between photodiodes.

After the epitaxial silicon is formed in the trenches, the hard mask layer may be removed from the substrate. Photodiodes may then be implanted in the substrate under the portion of the substrate that the hard mask layer was previously covering.

The substrate in which the trenches are formed may be made of epitaxial silicon. In this embodiment, the epitaxial silicon that forms the substrate may have a lower doping concentration than the epitaxial silicon formed in the trenches. For example, the substrate could be formed from epitaxial silicon doped with boron or antimony at a concentration between 10¹⁴ cm⁻³ and 10¹⁵ cm⁻³, and the epitaxial silicon in the trenches could be formed from epitaxial silicon doped with boron at a concentration between 10¹⁶ cm⁻³ and 10¹⁸ cm⁻³. The substrate may be disposed on a buried oxide layer or a p-type epitaxial substrate.

In various embodiments, the image sensor formed using the aforementioned methods may be part of a system including a central processing unit, memory, and input-output circuitry.

The foregoing is merely illustrative of the principles of this invention which can be practiced in other embodiments.

1. A method of forming an image sensor with an array of photodiodes in a substrate and a plurality of isolation regions that isolate each photodiode in the array of photodiodes, comprising:
before implanting the photodiodes in the substrate, forming trenches in the substrate in the isolation regions;
before forming the trenches in the substrate, forming a hard mask layer over a portion of the surface of the substrate, wherein forming the trenches in the substrate comprises performing an etching process, wherein the hard mask layer is resistant to the etching process;
forming doped epitaxial silicon in the trenches; and
removing the hard mask layer from the substrate after forming the doped epitaxial silicon in the trenches.

2-4. (canceled)

5. The method defined in claim 1, further comprising implanting photodiodes in between the trenches after removing the hard mask layer from the substrate.

6. The method defined in claim 5, wherein the photodiodes are implanted under the portion of the surface of the substrate.

7. The method defined in claim 1, wherein the doped epitaxial silicon is formed in the trenches via epitaxial growth that occurs at temperatures between 600° C. and 700° C.

8. The method defined in claim 1, wherein the doped epitaxial silicon is doped with boron at a concentration between 10¹⁶ cm⁻³ and 10¹⁸ cm⁻³.

9. The method defined in claim 8, wherein the substrate is epitaxial silicon doped with boron at a concentration between 10¹⁴ cm⁻³ and 10¹⁵ cm³.

10. The method defined in claim 1, wherein the doped epitaxial layer is formed in the trenches via epitaxial growth with in situ doping.

11. The method defined in claim 1, wherein the substrate is disposed on a p-type epitaxial substrate.

12. An image sensor comprising:
a substrate containing an array of photodiodes, wherein the substrate comprises epitaxial silicon doped with a first concentration of an ion, wherein the substrate is disposed on a buried oxide layer; and
a plurality of isolation regions, wherein each isolation region is interposed between a pair of adjacent photodiodes in the array of photodiodes, wherein the isolation regions comprise epitaxial silicon doped with a second concentration of the ion.

13. The image sensor defined in claim 12, wherein the second concentration is greater than the first concentration.

14. The image sensor defined in claim 12, wherein the second concentration is between 10¹⁶ cm⁻³ and 10¹⁸ cm⁻³.

15. (canceled)

16. (canceled)

17. The image sensor defined in claim 12, wherein the ion comprises an ion selected from the group consisting of: boron (B) and antimony (Sb).

18. A system, comprising:
a central processing unit;
memory;
input-output circuitry; and
an imaging device, wherein the imaging device comprises an image sensor having an array of image pixels and wherein the image sensor comprises:
a substrate comprising epitaxial silicon;
an array of photodiodes formed in the substrate;
an array of isolation regions in the substrate, wherein each isolation region is interposed between a respective pair of photodiodes in the array of photodiodes and wherein the isolation regions comprise epitaxial silicon, wherein the epitaxial silicon comprises boron-doped epitaxial silicon that has a concentration of boron between 10¹⁶ cm⁻³ and 10¹⁸ cm⁻³, and wherein the substrate comprises additional boron-doped epitaxial silicon that has a concentration of boron between 10¹⁴ cm⁻³ and 10¹⁵ cm⁻³.

19. (canceled)

20. (canceled)
